(19) United States
(12) Patent Application Publication
(10) Pub. No.: US 2010/0327964 A1
(43) Pub. Date: Dec. 30, 2010

(54) Semiconductor device and method of removing semiconductor device noise

(75) Inventor: Rika Wakita, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC Electronics Corporation, Kawasaki (JP)

(21) Appl. No.: 12/801,247

(22) Filed: May 28, 2010

(30) Foreign Application Priority Data
Jun. 30, 2009 (JP) 2009-154589

(51) Int. Cl. H03B 1/00

(52) U.S. Cl. 327/551

(57) ABSTRACT

A semiconductor device includes: a noise detecting circuit; an input signal delaying circuit; and a mask circuit. The noise detecting circuit detects noise superimposed on an input signal and outputs a mask signal during a predetermined time period. The input signal delaying circuit delays the input signal and outputs a delay signal thereof. The mask circuit outputs an output signal in which the delay signal is masked based on the mask signal.

### INCORPORATION BY REFERENCE

This application is based upon and claims the benefit of priority from Japanese patent application No. 2009-154589 filed on Jun. 30, 2009, the disclosure of which is incorporated herein in its entirety by reference.

### BACKGROUND OF THE INVENTION

1. Field of the Invention

The present invention relates to a semiconductor device and a method of removing semiconductor device noise.

2. Description of Related Art

It is well known that errors occur in an electronic device due to electrostatic discharge (ESD) from a human body or other charged objects. In association with sophistication of the electronic device, immunity to the ESD has become increasingly important. International Electrotechnical Commission defines as IEC61000-4-2 an immunity test for the ESD. Also for a cellular phone or the like, an immunity test using a tester (ESD-Gun) is carried out on a main body and a display panel module. On a conductive portion of a casing, a contact discharge test is performed, and on a nonconductive portion thereof, an aerial discharge test is performed. A criterion is that even when an image displayed on a display panel is disturbed at the instant of discharge, normal display is restored immediately thereafter. Thus, increasing demands imposed on a display device IC (Integrated Circuit) loaded in the display panel is durability that no error occurs during an operation in addition to durability that no surge destruction occurs during an ESD destructive test.

The display driver IC of the cellular phone or the like has a display control circuit provided with a sequential circuit including a flip-flop and a combinational circuit including an OR circuit an AND circuit. The sequential circuit holds as binary logic information a command received from a CPU (Central Processing Unit), a time-series varying state inside the display driver IC and the like. Typically, the display driver IC is initialized by a reset signal asynchronously supplied from an input terminal, for the purpose of stabilizing the internal state at time of system activation. That is, the internal sequential circuit is initialized and starts its operation always from the same state. After the initialization, information such as operation condition is set through the CPU, and display operation is started.

When the display driver IC is mounted in the device, a long signal wiring is pulled out to the display panel. Thus, a terminal of the display driver IC is in ESD-susceptible environment. In particular, when the reset signal has been disturbed, the information held in the internal sequential circuit is initialized as described above. However, setting of operation condition and the like thereafter are not performed, and thus the display driver IC encounters a display error and no longer can achieve self-recovery. Therefore, for the reset signal, a powerful noise removing circuit against the electrostatic discharge (ESD) is required.

For removing short pulse noise, for example, as described in Japanese Patent Publication No. JP-A-Heisei 6-132791, an integration circuit with a combination of a capacitor and a resistor or a circuit with a combination of a delay circuit and an AND circuit is used. A technique of removing noise with an integration circuit is typically used as a circuit that removes noise mixed from an outside of the IC. Moreover, the circuit with the combination of the delay circuit and the AND circuit is frequently used as a circuit provided as countermeasure against digital circuit hazard.

As a countermeasure against the electrostatic discharge, the former integration circuit is used in many cases, and capacity of the capacitor and resistance of the resistor may be increased to improve tolerability. However, there are limitations on sizes of the resistor and the capacitor that are loadable inside the display driver IC, and thus it is difficult to mount an integration circuit having a great capacity and resistance. Moreover, when continuous noise has been inputted, the integration circuit may become saturated. That is, a filter function may deteriorate and the noise may not be removed completely.

Moreover, noise wraps around the display driver IC from the casing or the display panel via a joining part or the like. Thus, a peak voltage, a frequency, attenuating oscillation and so on of the noise differ depending on design of a display device, so that a noise waveform is not uniform, which makes it difficult to make estimation.

Japanese Patent Publication No. JP 2002-217695A describes a technique related to a noise removing circuit that removes noise added to a data signal inputted from outside to an input terminal. This noise removing circuit is provided with a noise removing level changing part and a control part. The noise removing level changing part changes setting of a noise removing level for the input terminal. The noise removing level whose setting is changed has a hysteresis characteristic for the data signal and this characteristic is changed. The control part performs control of change of the noise removing level on the noise removing level changing part.

Moreover, Japanese Patent Publication No. JP-A-Showa 60-137121 discloses a chattering preventing circuit. The chattering preventing circuit is provided with a switch, a pulse generating circuit, a delay circuit, and an AND circuit. The pulse generating circuit detects a rising edge part of a pulse connected to the switch and generates a pulse having a predetermined time width. The delay circuit is connected to a terminal of the switch to which the pulse generating circuit is connected, and delays a switching signal. The AND circuit takes AND of both outputs of the pulse generating circuit and the delay circuit. The chattering preventing circuit masks a chattering pulse by a pulse having a width longer than chattering generation time generated by chattering of the switch.

Further, Japanese Patent Publication No. JP-A-Heisei 1-305719 describes a technique related to a signal detector which, upon reception of an input pulse signal with noise superimposed thereon, detects it as a signal when amplitude of the input pulse signal is larger than a set threshold value. The signal detector is provided with first and second threshold value generating circuits, first and second amplitude comparison circuits, and a time ratio discrimination circuit. The first and second threshold value generating circuits generate first and second threshold values set so that a ratio of the first to second threshold values becomes constant and also amplitude of the second threshold value becomes larger. The first and second amplitude comparison circuits receives the first and second threshold values and output a quantized pulse signal detected by comparing amplitudes of these threshold values and the input pulse signal. The time ratio discrimination circuit receives the quantized pulse outputted from the first amplitude comparison circuit and calculates a time ratio between a sum of periods in which this quantized pulse signal is detected within a predetermined time and a sum of periods in which it is not detected. Moreover, the time ratio discrimination circuit increases or decreases the first threshold value in such a manner as to decrease or increase the time ratio in correspondence with the time ratio becoming equal to or larger than a predetermined value or becoming equal to or smaller than this value. Then the time ratio discrimination circuit controls the first threshold value generating circuit so that this amplitude lies in the vicinity of amplitude of the noise always superimposed on the input pulse signal.

It is desired to provide a semiconductor device loaded with a noise removing circuit capable of more reliable noise removing and a method of removing noise.

### SUMMARY

The present invention seeks to solve one or more of the above problems, or to improve upon those problems at least in part.

In one embodiment, a semiconductor device includes: a noise detecting circuit configured to detect noise superimposed on an input signal and output a mask signal during a predetermined time period; an input signal delaying circuit configured to delay the input signal and output a delay signal thereof; and a mask circuit configured to output an output signal in which the delay signal is masked based on the mask signal.

In another embodiment, a method of removing semiconductor device noise, includes: detecting noise superimposed on an input signal; delaying the input signal; and masking a delay signal in which the input signal is delayed when detecting the noise.

The present invention can provide a semiconductor device loaded with a noise removing circuit capable of more reliable noise removal and a method of removing noise.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 is a diagram showing a configuration of a display device according to an embodiment of the present invention;

FIG. 2 is a diagram showing a configuration of a control circuit according to the embodiment of the present invention;

FIG. 3 is a diagram showing a configuration of a display control circuit according to the embodiment of the present invention;

FIG. 4 is a diagram showing a command example of a display driver according to the embodiment of the present invention;

FIG. 5 is a diagram illustrating an operation of the display control circuit according to the embodiment of the present invention;

FIG. 6 is a diagram showing a configuration of a noise detecting circuit according to the embodiment of the present invention;

FIG. 7 is a diagram illustrating an operation of a noise removing circuit according to the embodiment of the present invention;

FIG. 8 is a diagram showing a configuration of a noise removing circuit provided with a plurality of noise detecting circuits according to the embodiment of the present invention;

FIG. 9 is a diagram showing an arrangement example of the noise detecting circuit according to the embodiment of the present invention; and

FIG. 10 is a diagram illustrating operation of the noise removing circuit provided with the plurality of noise detecting circuits according to the embodiment of the present invention.

### DESCRIPTION OF THE PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposed.

An embodiment of the present invention will be described below referring to the accompanying drawings.

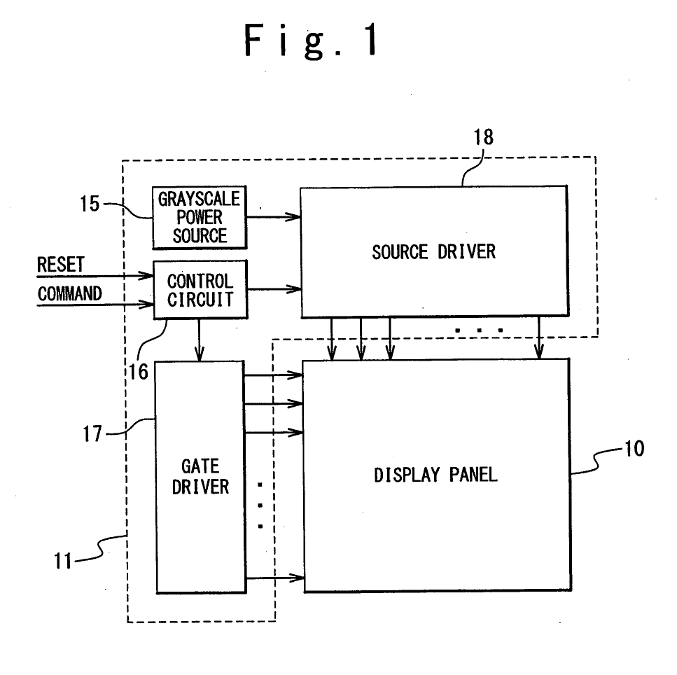

FIG. 1 is a block diagram showing a configuration of a display device according to the embodiment of the present invention. The display device includes: a display panel 10 displaying an image; and a display driver 11 driving the display panel 10. Application of the present invention is not limited to the display driver, but the display driver is illustrated as an example of the semiconductor device here.

The display driver 11 includes: a grayscale power source 15, a control circuit 16, a gate driver (scan electrode driving circuit) 17, and a source driver (data electrode driving circuit) 18, and drives the display panel 10. The display panel 10 is, for example, an active-matrix-driven liquid crystal panel using thin-film transistors (TFT) for switch elements.

The control circuit 16 is supplied with a dot clock signal, a horizontal synchronization signal and a vertical synchronization signal, a data enable signal and so on from outside (not shown). The control circuit 16, based on these input signals, generates a strobe signal, a clock signal, a horizontal scanning pulse signal, a polarity signal, a vertical scanning pulse signal and so on, and supplies them to the gate driver 17 and the source driver 18. Moreover, the control circuit 16 receives from the outside a command indicating an operation and then performs the operation indicated by the command, and receives a reset signal and then initializes the display driver 11.

The gate driver 17 sequentially generates a gate pulse in synchronization with timing of the vertical scanning pulse signal supplied from the control circuit 16, and supplies it to the display panel 10. The grayscale power source 15 generates grayscale voltages for setting grayscale at time of displaying an image on the display panel 10 and supplies them to the source driver 18. The source driver 18, based on image data inputted by using a digital signal, converts into an analog signal the image data by using the supplied grayscale voltages, and supplies it to the display panel 10.

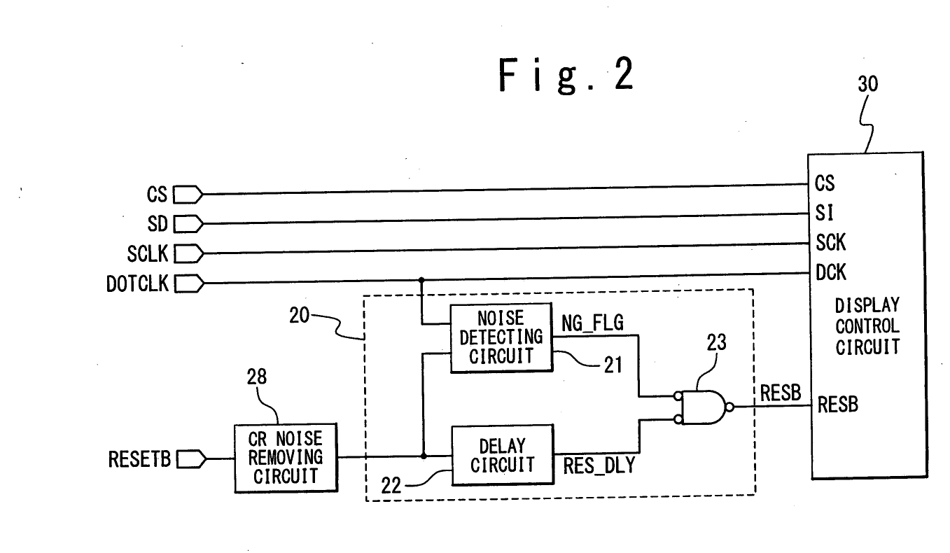

As described above, in the display driver 11, the control circuit 16 is a circuit which receives and outputs signals from and to the outside and which is most susceptible to ESD. The control circuit 16, as shown in FIG. 2, includes: a display control circuit 30, a noise removing circuit 20, and a CR noise removing circuit 28. The display control circuit 30 is a main body portion of the control circuit 16, and has a logic circuit performing various controls. The CR noise removing circuit 28 is an integration circuit provided with a resistor and a capacitor, and removes slight noise superimposed on a reset signal RESETB inputted to the display driver 11. The CR noise removing circuit 28 may be omitted.

The noise removing circuit 20 includes: a noise detecting circuit 21, a delay circuit 22, and a negative logic AND circuit 23. The noise detecting circuit 21 receives a clock signal DOTCLK and the reset signal RESETB, and outputs a mask signal NG_FLG to the negative logic AND circuit 23. The reset signal RESETB may be inputted to the noise detecting circuit 21 via the CR noise removing circuit 28 or not via the CR noise removing circuit 28. The noise detecting circuit 21, upon noise detection, turns its output NG_FLG to a high level. The delay circuit 22 outputs to the negative logic AND circuit 23 a reset signal RES_DLY obtained by delaying the reset signal RESETB. The negative logic AND circuit 23, when both the mask signal NG_FLG and the delay reset signal RES_DLY are at a low level, turns a reset signal RESB as an output to a low level. Therefore, while the noise detecting circuit 21 keeps the mask signal NG_FLG at the high level as a result that the noise is detected, the reset signal RESB inputted to the display control circuit 30 is fixed at a high level. That is, when the noise is detected by the noise detecting circuit 21, the delay reset signal RES_DLY is masked by the mask signal NG_FLG, and the reset signal RESB with the noise removed is generated. Here, the reset signal RESETS, the mask signal NG_FLG, and the delay reset signal RES_DLY indicate negative logic signals, and signals that are active at a low level. Thus, the negative logic AND circuit 23 is expressed by negative logic and equivalent to a positive logic OR circuit.

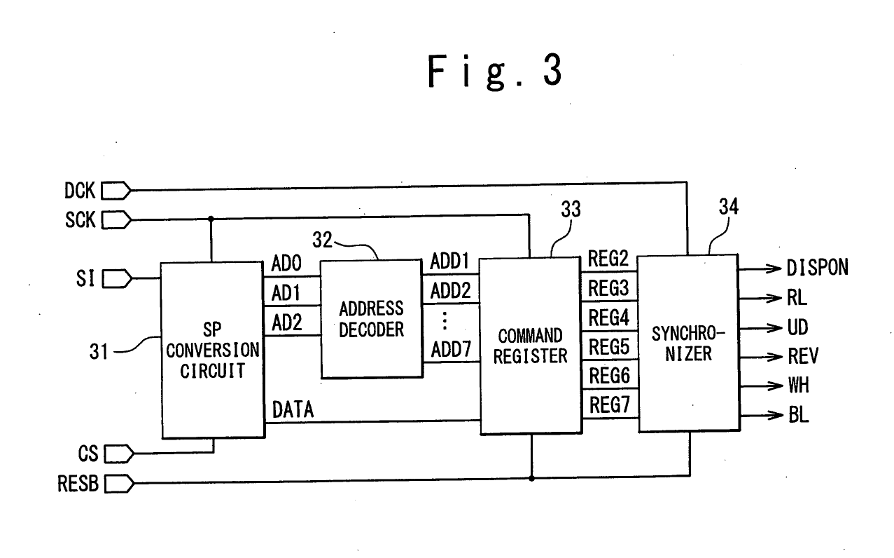

FIG. 3 shows a configuration of the display control circuit 30. The display control circuit 30 includes: a serial-parallel conversion circuit 31, an address decoder 32, a command register 33, and a synchronizer 34. The display control circuit 30 receives and analyzes a command transmitted from a host device, and outputs a control signal to the various parts. The serial-parallel conversion circuit 31, based on a chip select signal CS, receives a serial data signal SI (signal SD upon input to a chip) in synchronization with a serial clock signal SCK (signal SCLK upon input to the chip). The serial-parallel conversion circuit 31 converts serial data into parallel address signals AD0 to AD2, outputs them to the address decoder 32, and outputs a data signal DATA to the command register 33.

The address decoder 32 decodes the 3-bit address signals AD0 to, AD2, and output to the command register 33 signals ADD1 to ADD7 that become active in correspondence with respective addresses. The command register 33, based on the signals ADD1 to ADD7 and the data signal DATA, holds command data and outputs to the synchronizer 34 signals REG2 to REG7 corresponding to the command. The synchronizer 34 synchronizes the signals REG2 to REG7 based on a clock signal DCK (signal DOTCLK upon input to the chip) and supplies them as command signals to the various parts. The command register 33 and the synchronizer 34 are rest by the reset signal RESB.

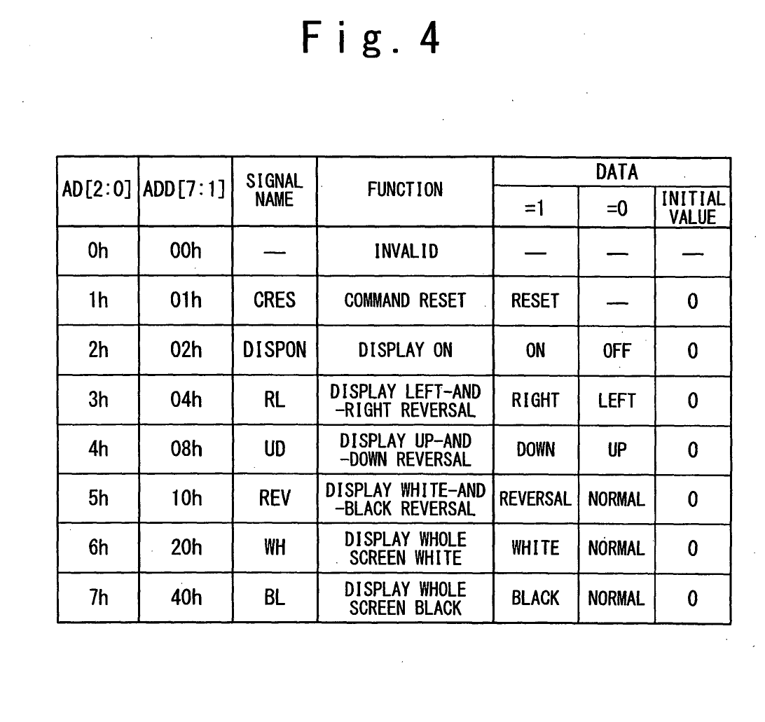

Here, there are seven kinds of commands as shown in FIG. 4. Assigned in correspondence with the addresses are: Command reset (CRES), Display on (DISPON), Display left-and-right reversal (RL), Display up-and-down reversal (UD), Display white-and-black reversal (REV), Display whole screen white (WH), and Display whole screen black (BL). Their initial values are all “0”. When the reset signal RESB has been inputted, this initial value is set. For example, DISPON=1 indicates display start, and DISPON=0 indicates display stop. Therefore, the display is stopped by resetting.

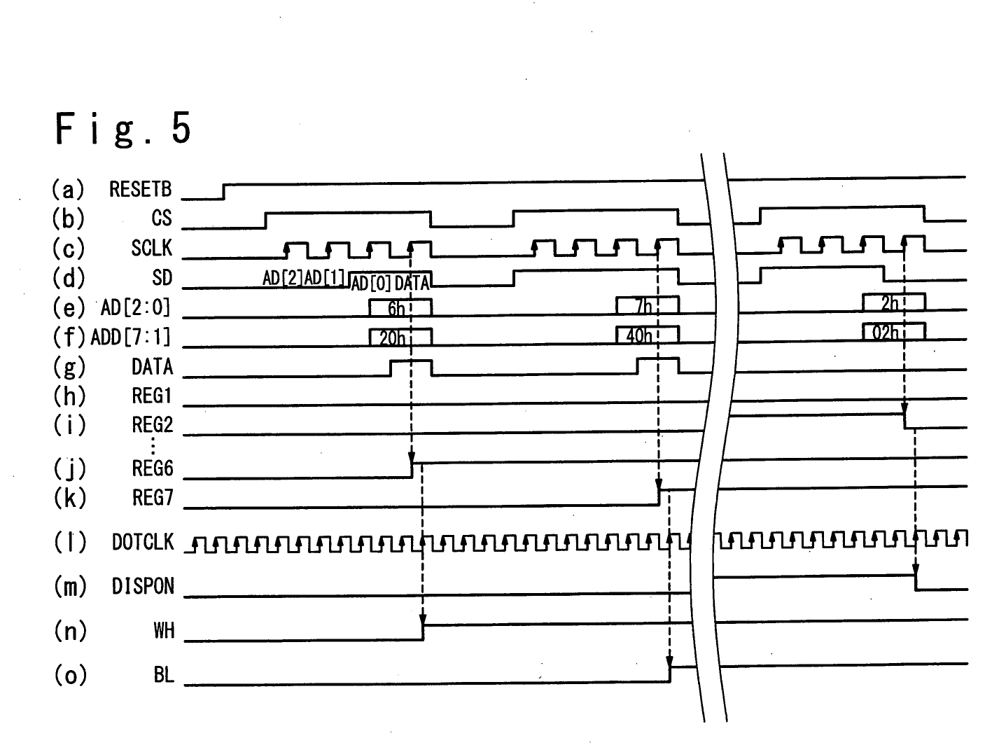

FIG. 5 shows an operation of the display control circuit 30. As shown in (a) in FIG. 5, prior to the operation, the rest signal RESETB turns to a high level and the resetting is released. Command input timing is indicated by the chip select signal CS ((b) in FIG. 5). In synchronization with a rising edge of the clock signal SCLK (signal SCK in the display control circuit 30) ((c) in FIG. 5), the data signal SD (signal SI in the display control circuit 30) is received. The address signals AD0 to AD2 subjected to parallel conversion are shown in (e) in FIG. 5, and the signals ADD1 to ADD7 obtained by decoding them are shown in (f) in FIG. 5. The signal DATA received at a fourth rising edge of the clock signal SCLK is shown in (g) in FIG. 5. A value indicated by the data signal DATA is reflected at a position of the command register 33 indicated by the signals ADD1 to ADD7. Here, for a first chip select signal CS, AD [2:0]=6h (110) is inputted, the ADD6 turns to “1”, and since DATA=1, REG6 changes to “1” ((j) in FIG. 5). For a second chip select signal CS, AD [2:0]=7h (111) is inputted, the ADD7 turns to “1”, and since DATA=1, REG7 changes to “1” ((k) in FIG. 5). For a third chip select signal CS, AD [2:0]=2h (010) is inputted, the ADD2 turns to “1”, and since DATA=0, REG2 changes to “0” ((i) in FIG. 5). The data set in the command register 33, in synchronization with rising edges of the clock signal DOTCLK ((l) in FIG. 5: the signal DCK in the display control circuit 30), are respectively supplied to the various parts as a corresponding signal WH ((n) in FIG. 5), a signal BL ((o) in FIG. 5), and a signal DISPON ((m) in FIG. 5).

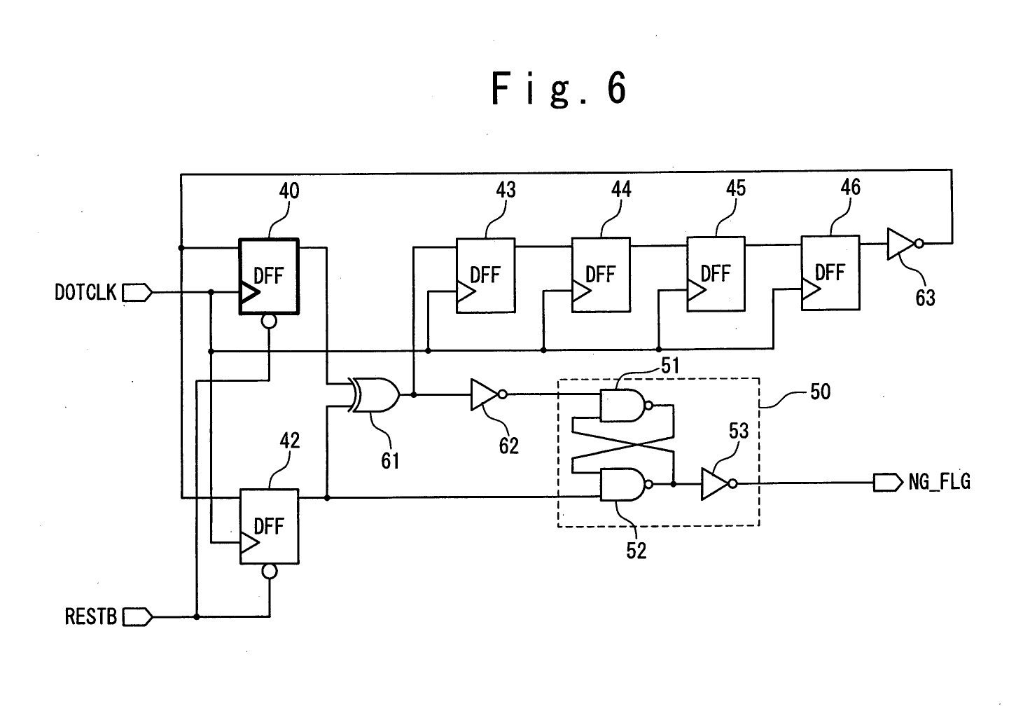

FIG. 6 shows a configuration of the noise detecting circuit 21. The noise detecting circuit 21 includes: a flip-flop 40; flip-flops 42 to 46; an EXOR circuit 61; NOT circuits 62 to 63, and an RS flip-flop 50. The flip-flop 40 is a D-type flip-flop so designed as to sensitively respond to noise. The flip-flops 42 to 46 are normal D-type flip-flops. The RS flip-flop 50 here includes: two NAND circuits 51 and 52, and an NOT circuit 53.

The flip-flops 40 and 42 both receive an output of the NOT circuit 63 based on a rising edge of the clock signal DOTCLK, and is reset by the reset signal RESETB in an asynchronous manner. Outputs Q40 and Q42 of the flip-flops 40 and 42 are inputted to the EXOR circuit 61. The output Q42 of the flip-flop 42 is also inputted to the RS flip-flop 50. An output EOR 61 of the EXOR circuit 61 is inputted to the flip-flops 43 to 46 continuously connected, and is sequentially transmitted to the flip-flops at later stages based on the clock signal DOTCLK. An output Q46 of the flip-flop 46 is inputted to the flip-flops 40 and 42 via the NOT circuit 63. Here, the number of stages of flip-flops continuously connected is four, but since mask time of the noise detecting circuit 21 is set depending on this number of stages, it is preferable that the number of stages be provided based on the mask time.

The output EOR 61 of the EXOR circuit 61 is also inputted to the NOT circuit 62, logic of which is inverted and then inputted to the RS flip-flop 50. The RS flip-flop 50 is set by the output of the EXOR circuit 61 inverted by the NOT circuit 62, and is reset by the output Q42 of the flip-flop 42. The EXOR circuit 61 indicates whether or not the output Q40 of the flip-flop 40 and the output Q42 of the flip-flop 42 agree with each other. Therefore, the RS flip-flop 50 is set when the output of the flip-flop 40 and the output of the flip-flop 42 disagree with each other. Moreover, when the flip-flop 42 turns into a rest state, the RS flip-flop 50 is reset. An output of the RS flip-flop 50 is supplied as the mask signal NG_FLG to the negative logic AND circuit 23.

Typically, the output of the flip-flop 40 and the output of the flip-flop 42 agree with each other; therefore, the output EOR 61 of the EXOR circuit 61 is at a low level, and a high level inverted by the NOT circuit 63 is inputted to the flip-flop 40 and the flip-flop 42. That is, the flip-flop 40 and the flip-flop 42 hold its set state. When reset by the reset signal RESETB, the flip-flop 40 and the flip-flop 42 holds their reset states until this reset ends and the clock signal DOTCKL further rises. Note that even in the reset state, the outputs of the flip-flop 40 and the flip-flop 42 agree with each other; therefore, the output of the EXOR circuit 61 is at a low level.

When the outputs have disagreed with each other, a signal indicating the disagreement is delayed by the flip-flops 43 to 46, turning the flip-flops 40 and 42 into a rest state. This resets the RS flip-flop 50, so that the flip-flops 43 to 46 determine time provided until the RS flip-flop 50 is reset, that is, the mask time.

The flip-flops 40 and 42 have asynchronous reset inputs, and are reset by a reset signal RESET. Moreover, both the flip-flops 40 and 42 receive the output of the NOT circuit 63 based on the clock signal DOTCLK, and outputs it to the EXOR circuit 61. Therefore, the flip-flops 40 and 42 normally perform the same operation. The flip-flop 40 sensitively responds to noise, and thus it turns into a rest state in response to noise superimposed on the reset signal RESETB before the flip-flop 42 responds thereto. At this point, the flip-flop 40 and the flip-flop 42 come to be in disagreement with each other, and the EXOR circuit 61 outputs a high level, turning the RS flip-flop 50 into a set state. When a regular reset signal has been inputted, the output of the EXOR circuit 61 is at a low level and the output Q42 of the flip-flop 42 turns into a low level, thus resetting the RS flip-flop 50. At this point, even when the flip-flop 40 responds beforehand, resulting in disagreement, the RS flip-flop 50 is reset by turning of the output Q42 of the flip-flop 42 into the low level.

Time delayed by the delay circuit 22 may be at least time provided until the noise is detected and the mask signal NG_FLG is outputted from the RS flip-flop 50. Here, the display driver 11 is a synchronous type circuit, and a clock signal with a shortest cycle is the clock signal DOTCLK; therefore, the delay circuit 22 provides the reset signal RESETB with a delay of one cycle of the clock signal DOTCLK and outputs the delay reset signal RES_DLY.

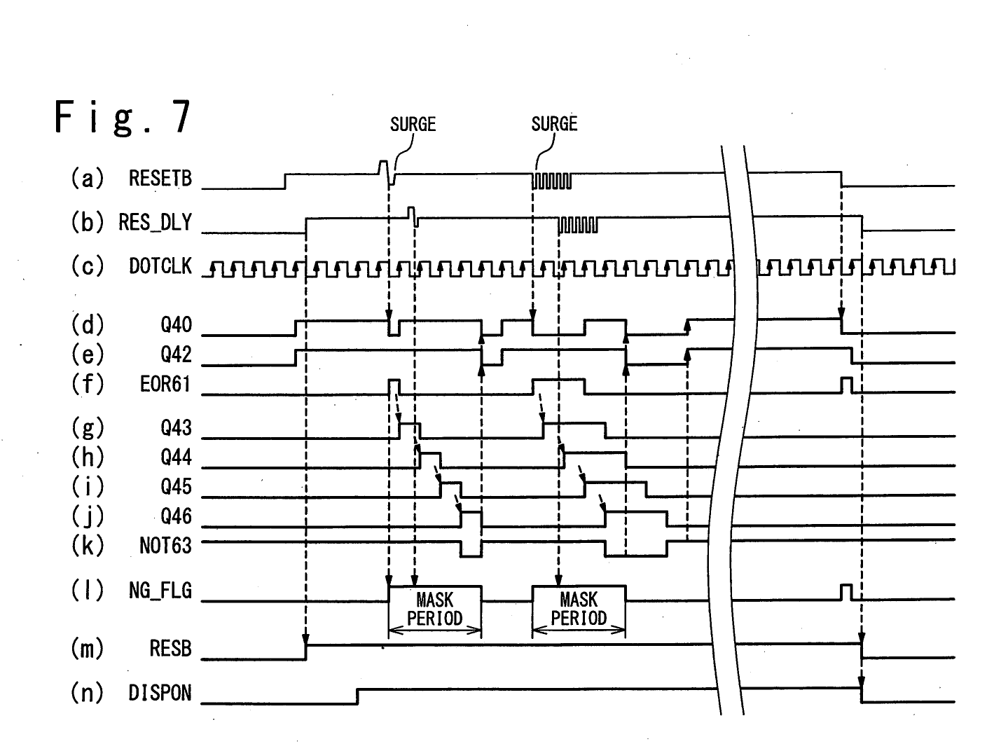

FIG. 7 shows an operation of the control circuit 16 provided with the noise removing circuit 20 described above.

The reset signal RESETB is a system initialization signal for the display driver 11, and when it is at a low level, the display control circuit 30 and the flip-flops included in the noise detecting circuit 21 sets initial values. The flip-flops 43 to 46 may also be reset by a reset signal, although no reset signal is inputted to the flip-flops 43 to 46 as shown in the figure. Flip-flops, like the flip-flops 43 to 46, which are not reset by a reset signal are initialized by inputting the clock signal DOTCLK during a period in which the reset signal RESETB is at a low level.

As shown in (a) in FIG. 7, the reset signal RESETB indicates reset release and the operation starts. After the reset has been released, the flip-flop 40 and the flip-flop 42 turn into a set state ((d) and (e) in FIG. 7) in synchronization with rising edges of the clock signal DOTCLK as shown in (c) in FIG. 7. The mask signal NG_FLG as the output of the RS flip-flop 50 indicates a low level (Noise not detected) as shown in (l) FIG. 7, and thus the delay reset signal RES_DLY ((b) in FIG. 7) is directly outputted as the reset signal RESB ((m) in FIG. 7) via the negative logic AND circuit 23. At this point, the reset signal RESB indicates reset release and the display control circuit 30 starts the normal operation.

Here, a display command indicating display start is transmitted from a host, and the display control circuit 30 turns the signal DISPON to a high level as shown in (n) in FIG. 7. When the signal DISPON has turned to the high level, the display starts.

Noise is added to the reset signal RESETB by a surge during the display, and the flip-flop 40, in response thereto, turns the output Q40 to a low level. Since the surge is temporary, the flip-flop 40 restores its original state ((d) in FIG. 7) in synchronization with the rising edge of the clock signal DOTCLK. On the other hand, the flip-flop 42 does not respond to the noise, and its output Q42 disagrees with the output 40 of the flip-flop 40. Therefore, the output EOR 61 of the EXOR circuit 61 temporarily turns to a high level ((f) in FIG. 7), setting the RS flip-flop 50 and turning the output NG_FLG to a high level ((l) in FIG. 7). From this point, the mask period starts.

The flip-flops 43 to 46 sequentially transmit the high level state of the output EOR 61 in synchronization with the clock signal DOTCLK ((g) to (j) in FIG. 7). The output Q46 of the flip-flop 46 is logically inverted by the NOT circuit 63 ((k) in FIG. 7), and supplied to the flip-flops 40 and 42 ((d) and (e) in FIG. 7) at the rising edge of the clock signal DOTCLK. When the output Q42 of the flip-flop 42 has turned to a low level, the RS flip-flop 50 is reset and the output NG_FLG turns to a low level ((l) in FIG. 7). Here, the mask period ends.

In this mask period, the delay reset signal RES_DLY ((b) in FIG. 7) is masked by the mask signal NG_FLG, and thus even when noise generated by the surge is superimposed on the delay reset signal RES_DLY, there is no influence on the reset signal RESB ((m) in FIG. 7). Therefore, the signal DISPON is not influenced by the surge and maintains its state ((n) in FIG. 7).

Upon reception of a continuous surge, a period during which the output Q40 of the flip-flop 40 indicates a low level becomes long ((d) in FIG. 7), and a period during which the output EOR 61 of the EXOR circuit 61 indicates disagreement becomes long ((f) in FIG. 7). Thereafter, the same operation as that at a single surge is performed. By the number of stages of the flip-flops shifting a disagreement state and by a cycle of the clock signal DOTCLK, a time period for removing continuous noise (mask period) can be adjusted.

Note that, as shown on a right side in FIG. 7, even if there is a difference in response time to an input of a valid reset signal RESETB between the flip-flop 40 and the flip-flop 42, when the flip-flop 42 has been reset, the mask signal NG_FLG is also thereby reset, with no influence exerted on the reset signal RESB. Therefore, both the flip-flop 40 and the flip-flop 42 are of an asynchronous reset type in the above description. However, a flip-flop of a synchronous reset type has typically greater strength against asynchronous noise, and thus the flip-flop 42 may be of a synchronous reset type.

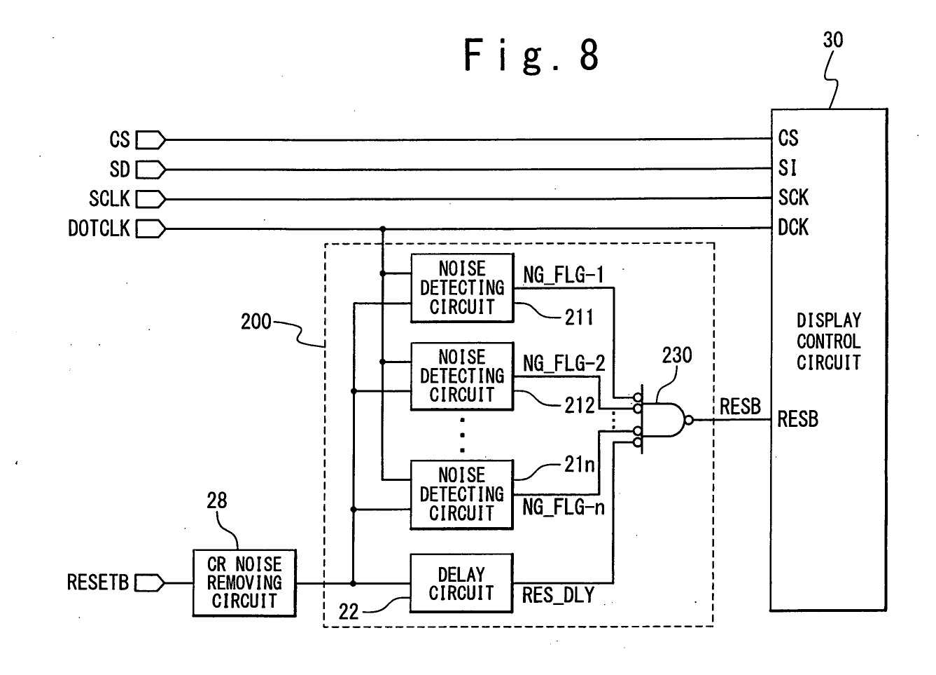

The noise detecting circuit 21 is a single circuit in the above description. However, a plurality of noise detecting circuits 21 may be provided for dealing with noise whose input path is unclear. FIG. 8 shows a configuration of a noise removing circuit 200 provided with a plurality of noise detecting circuits 211 to 21n. When any one of mask signals NG_FLG-1 to NG_FLG-n outputted from the plurality of noise detecting circuits 211 to 21n has indicated noise detection, the delay reset signal RES_DLY is masked by a negative logic AND circuit 230.

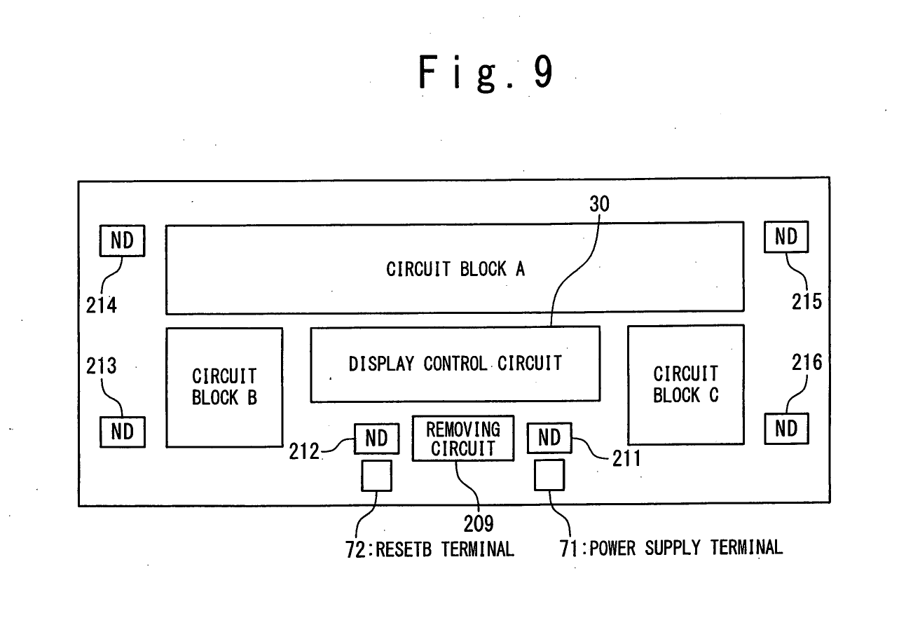

The plurality of noise detecting circuits 211 to 21n can be so arranged as to be dispersed at noise-susceptible sections on the chip of the display driver 11. A reset signal terminal and a power supply terminal whose signal lines are directly pulled out to the outside and chip periphery are susceptible to noise. Therefore, as shown in FIG. 9, noise detecting circuits (ND) 211 to 216 can be arranged in the vicinity of a reset terminal 72, in the vicinity of a power supply terminal 71, and at a chip peripheral portion. In addition, a removal circuit 209 including a delay circuit 22 and a negative logic AND circuit 230 can be arranged in the vicinity of the reset terminal 72 to thereby improve noise removal effect.

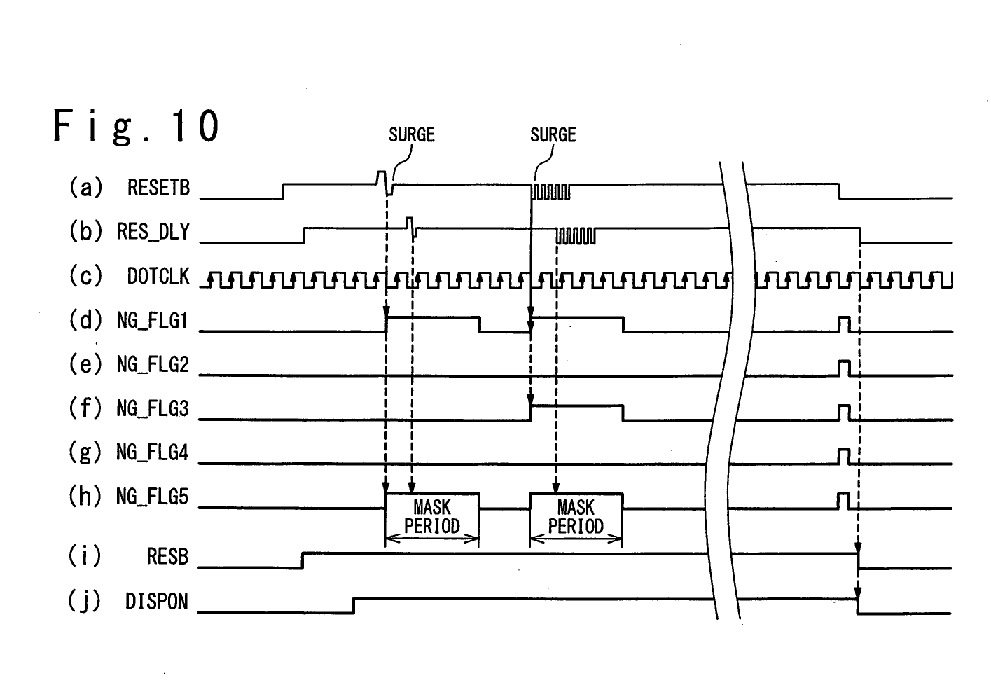

As shown in FIG. 10, noise generated by a short surge is detected by the noise detecting circuits 211 and 215 whereby the mask signals NG_FLG1 and NG_FLG5 turn to a high level, and noise generated by a continuous surge is detected by the noise detecting circuits 211 and 213 whereby the mask signals NG_FLG1 and NG_FLG3 turn to a high level. In either state, the delay reset signal RES_DLY is masked, with no influence exerted on the reset signal RESB.

In the above description, the flip-flop 40 responds sensitively to noise. However, such a flip-flop can by realized by a general technique. For example, this can be realized by reducing a transistor size. Power supply may be restricted by providing a power source wiring with slight resistance. Such a flip-flop can also be realized by disturbing balance between an N-channel transistor and a P-channel transistor. This can be realized by any other method or by combining together those described above.

In the noise detecting circuit 21, the reset signal RESETB is commonly inputted to the flip-flop 40 and the flip-flop 42. However, the reset signal RESETB may be inputted to a reset input node of the flip-flop 40 without via the CR noise removing circuit 28. Moreover, the reset signal RESETB may be inputted to a reset input node of the flip-flop 42 via a more powerful CR noise removing circuit. Further, the reset signal RESETB may be inputted to an asynchronous reset input node of the flip-flop 40 and to a synchronous data input node or a synchronous reset input node of the flip-flop 42. In this case, when a valid reset signal has been received, the outputs once disagree with each other, but thereafter the both flip-flops turn into the same reset state by a synchronization signal, thus resulting in no change in the effect.

In the above embodiment, the noise removal from the reset signal has been illustrated. However, this can also be applied to a different signal. Since a target signal is delayed by the delay circuit 22, this cannot be applied to a signal with which timing is important, but can be applied to any signal, like a reset signal, which transmits data depending on a voltage level.

As described above, in the present invention, noise is detected by the noise detecting circuit earlier than by a protection target circuit and a noise component is masked. As a result, ESD-generated noise is removed. A conventionally adopted method of avoiding abnormal operation is directly removing noise superimposed on an asynchronous reset signal that resets a flip-flop or the like, but this results in abnormal operation due to failure to completely remove the noise in some cases. In the present invention, the noise can be detected before detected by the protection target circuit and a signal to the protection target circuit with noise superimposed thereon can be masked. Therefore, immunity durability improves and reliability increases. Moreover, an immunity test permissible dose improves and wasted cost for redesigning due to an insufficient permissible dose can be eliminated.

It is apparent that the present invention is not limited to the above embodiment, but may be modified and changed without departing from the scope and spirit of the invention.

Although the present invention has been described above in connection with several exemplary embodiments thereof, it would be apparent to those skilled in the art that those exemplary embodiments are provided solely for illustrating the present invention, and should not be relied upon to construe the appended claims in a limiting sense.

What is claimed is:

1. A semiconductor device comprising:
a noise detecting circuit configured to detect noise superimposed on an input signal and output a mask signal during a predetermined time period;
an input signal delaying circuit configured to delay the input signal and output a delay signal thereof; and
a mask circuit configured to output an output signal in which the delay signal is masked based on the mask signal.

2. The semiconductor device according to claim 1, wherein noise detecting circuit includes:
a first flip-flop configured to be reset in response to any of the noise and the input signal,
a second flip-flop configured to be reset in response to the input signal,
an agreement determinating circuit configured to determine whether or not a first output of the first flip-flop agrees with a second output of the second flip-flop and output an disagreement signal if the first output disagrees with the second output,
a disagreement signal delaying circuit configured to delay the disagreement signal during the predetermined time period, and
a third flip-flop configured to be set in response to the disagreement signal and be reset when the second flip-flop is reset.

3. The semiconductor device according to claim 2, wherein the first flip-flop and the second flip-flop are asynchronously reset in response to the input signal.

4. The semiconductor device according to claim 2, wherein the first flip-flop is asynchronously reset in response to the input signal, and
wherein the second flip-flop is synchronized with a clock signal and is reset in response to the input signal.

5. The semiconductor device according to claim 2, wherein the second flip-flop and the input signal delaying circuit receive the input signal through an integration circuit.

6. The semiconductor device according to claim 5, wherein the first flip-flop receives the input signal through the integration circuit.

7. The semiconductor device according to claim 1, wherein noise resistance properties of the first flip-flop is inferior to that of the second flip-flop.

8. The semiconductor device according to claim 7, wherein a size of a transistor included in the first flip-flop is smaller than that of a transistor included in the second flip-flop.

9. The semiconductor device according to claim 7, wherein a power supply voltage supplied to the first flip-flop is lower than that supplied to the second flip-flop.

10. The semiconductor device according to claim 7, wherein a threshold voltage of a transistor included in the first flip-flop is lower than that of a transistor included in the second flip-flop.

11. The semiconductor device according to claim 1, wherein the noise detecting circuit is arranged in a vicinity of an input terminal where the input signal is supplied.

12. The semiconductor device according to claim 1, wherein the noise detecting circuit is arranged in a vicinity of a power supply terminal where power supply is performed.

13. The semiconductor device according to claim 1, further comprising:
a plurality of noise detecting circuits including the noise detecting circuit,
wherein the plurality of noise detecting circuit is arranged so as to be dispersed on a periphery of the semiconductor device.

14. The semiconductor device according to claim 1, wherein the input signal is a level signal which transmits data depending on a voltage level that a delay is allowed.

15. The semiconductor device according to claim 14, wherein the level signal is a reset signal initially set asynchronously.

16. A method of removing semiconductor device noise, comprising:
detecting noise superimposed on an input signal;
delaying the input signal; and
masking a delay signal in which the input signal is delayed when detecting the noise.

17. The method of removing semiconductor device noise according to claim 16, wherein the detecting step includes:
resetting a first flip-flop in response to the input signal,
resetting a second flip-flop in response to the input signal,
determinating whether or not a first output of the first flip-flop agrees with a second output of the second flip-flop,
resetting the first flip-flop and the second flip-flop after elapse of a predetermined time period if the first output disagrees with the second output,
setting a third flip-flop to output a mask signal if the first output disagrees with the second output, and
resetting the third flip-flop to release the mask signal when the second flip-flop is reset,
wherein the masking step includes:
masking the delay signal based on the mask signal.

18. The method of removing semiconductor device noise according to claim 17, further comprising:
setting noise resistance properties of the first flip-flop to be inferior to that of the second flip-flop.
